(19) United States
(12) Patent Application Publication
(10) Pub. No.: US 2018/0210115 A1
(43) Pub. Date: Jul. 26, 2018

(54) CONDUCTIVE COMPOSITION SOLUTION AND ANTISTATIC FILM AND PANEL DISPLAY THEREOF

(71) Applicant: eChem Solutions Corp., Longtan (TW)

(72) Inventors: HSIN-JEN CHEN, Longtan (TW); MENG-PO LIU, Longtan (TW)

(21) Appl. No.: 15/666,390

(22) Filed: Aug. 1, 2017

(30) Foreign Application Priority Data
Jan. 25, 2017 (TW) 106102940

(51) Int. Cl. G02B 1/16; C08L 65/00; C08L 25/18; C09D 165/00; C09D 125/18; C09D 5/24; C09D 7/06; C09D 7/12; C09D 7/00; G02F 1/1335; H01L 51/52; H01L 23/60

(52) U.S. Cl. CPC G02B 1/16; C08L 65/00; C08L 25/18; C09D 165/00; C09D 125/18; C09D 5/24; C08K 5/5415; C09D 7/1233; C09D 7/001; G02F 1/133528; H01L 51/52; H01L 23/60; C09D 7/06

(57) ABSTRACT

The present invention provides a conductive composition solution, comprising: an (A) conductive polymer, comprising: a Π-conjugated conductive polymer and a multivalent anionic polymer, wherein the multivalent anionic polymer is mixed with the Π-conjugated conductive polymer; a (B) alkoxy silane, having a weight percentage to the conductive composition solution in a range of 1-5.5 wt %; and a (C) solvent, comprising: a low-boiling-point solvent, having a boiling point in a range of 55-120° C.; a high-boiling-point solvent, having a boiling point in a range of 170-250° C., and being soluble in water; and water.

### FIELD OF THE INVENTION

The present invention relates to a conductive composition solution and antistatic film and panel display thereof. Especially, a conductive composition solution with fine leveling property, and the antistatic film thereof with the great hardness and is able to tolerate the surface resistance of the electronic display.

### BACKGROUND OF THE INVENTION

Recently, all kinds of displays have been broadly used, such as plasma display panel, organic electro-luminescence display (OELD), liquid crystal display (LCD), etc. The thin conductive film (e.g., indium tin Oxide (ITO)) has been widely used in the several products, such as panel displays, solar cells, touch panels, etc., to prevent people from the inconvenience of use or affect the element efficiency by the static charge accumulation. However, other than reasons of increasing price and the lack of materials, the touch panel is in the course of the need to regularly apply stress on the ITO film or bend it resulting in the ITO film ageing, or even cracks. In addition, an electronic resistance value of ITO material is up to 10³Ω/□ in general conditions. Therefore, it not only has to strictly controlled a thickness of the ITO film in the manufacturing process but also to provide the device/element with a higher voltage, which causes higher cost of electric power, in order to achieve a required electrostatic discharge effect. Accordingly, it is necessary to provide a new material to replace the conventional ITO film.

The conductive polymer becomes popular is because of several great properties, such as static electricity, durability, no dust-and-particle producing, thermal stability, hydrolysis resistance, etc. Furthermore, the conductive polymer is different from the ITO material, which is fragile and expensive, that it is cheap and with the resistance to bending, and thus it is able to improve the defect of the ITO material. Consequently, there are several industries starting to use the thin antistatic film material and apply it to the related products.

It is not easy to produce the antistatic film with high optical transparency and comply with requirements of products due to the physical and the chemical characteristics of the conductive polymer that conductive polymer is generally non-transparent, and also difficult to uniformly mix with organic polymers/monomers that leads to difficulties of synthesize, manufacture and application.

### SUMMARY OF THE INVENTION

The present invention provides a conductive composition solution, comprising: a (A) conductive polymer, comprising: a Π-conjugated conductive polymer and a multivalent anionic polymer, wherein the multivalent anionic polymer is mixed with the Π-conjugated conductive polymer; a (B) alkoxy silane, having a weight percentage to the conductive composition solution in a range of 1-5.5 wt %; and a (C) solvent, comprising: a low-boiling-point solvent, having a boiling point in a range of 55-120° C.; a high-boiling-point solvent, having a boiling point in a range of 170-250° C., and soluble in water; and water.

In the embodiment of the present invention, wherein the conductive polymer is poly(3,4-ethylenedioxythiophene)-poly (styrenesulfonate), and a weight ratio of the alkoxy silane (B) to the conductive polymer (A) is in a range of 35-100.

In the embodiment of the present invention, wherein a weight percentage of the low-boiling-point solvent to the solvent (C) is in the range of 55-81 wt %, a weight percentage of the high-boiling-point solvent to the solvent (C) is in the range of 1-15 wt %; and a weight percentage of the water to the solvent (C) is in the range of 10-30 wt %.

In the embodiment of the present invention, wherein the conductive composition solution, comprising: a leveling agent (D), having a weight percentage to the conductive composition solution in a range of 0.01-1.0 wt %.

In the embodiment of the present invention, wherein the leveling agent comprising at least one or any combination of the following: hydroxyl polyester modified siloxanes, acrylic ester copolymers, polyether modified siloxane leveling agents and aralkylalkyl modified siloxanes.

In the embodiment of the present invention, wherein the alkoxy silane comprising at least one or any combination of the following: tetramethoxysilanes, tetraethyl siloxanes, tetraethoxysilanes, tetraethyl orthosilicates and ethyl silicates.

In the embodiment of the present invention, wherein the low-boiling-point solvent comprising at least one or any combination of the following: isopropanol (IPA), ethanol and ketones.

In the embodiment of the present invention, wherein the high-boiling-point solvent comprising at least one or any combination of the following: ethylene glycols, high-carbon alcohols, N-Methylpyrrolidinones and dimethylsulfoxides.

In an aspect of the present invention, it provides an antistatic film formed by the conductive composition solution through a coating process and a curing process.

In another aspect of the present invention, it also provides an antistatic film, wherein the curing process is under 80-150° C. for 3-30 minutes.

In one embodiment of the present invention, wherein the hardness of antistatic film is 5H or above.

In one embodiment of the present invention, wherein the surface resistance of the antistatic film is in the range of 10⁶Ω/□˜10¹²Ω/□.

In an aspect of the present invention, it provides a panel display, including the antistatic film.

In one embodiment of the present invention, wherein the panel display including a polarizer, and that directly covers the antistatic film.

Therefore, the conductive composition solution of the present invention is able to be used as transparent colorless coating material or antistatic film coating solution having antistatic property conforming to an optical device without reducing visible range. Moreover, an antistatic film formed by cured conductive composition solution includes low amount of conductive polymer, and has low fog density, high hardness and anti-scratch property, and therefore it is suitable for used in growing the conductive coating layer applied in panel displays, such as LCD, OELD, etc. Because the antistatic film of the present invention includes conductive polymers and silane structure, it is able to replace expensive ITO layers/films or other higher cost antistatic material. The conductive composition solution of the present invention can be coated on a LCD cell of an electronic equipment/device or a light-emitting side of an OELD to effectively discharge electrostatics on a surface of the electronic device (i.e., preventing the electronic equipments from damage by electrostatic discharge (ESD)) and achieve desired antistatic effect. Using the conductive composition solution of the present invention as antistatic coating solution, it demonstrates several great characters, such as great leveling property after coating, the hardness greater than 5H to prevent damage by moving wheel of production line in manufacturing process, electronic resistance of a surface with the good discharging effects and without conducting an element circuit, and great weather resistance; and therefore the prevent invention can increase durability of products.

### BRIEF DESCRIPTION OF THE DRAWINGS

The present invention will become more readily apparent to those ordinarily skilled in the art after reviewing the following detailed description and accompanying drawings, in which:

FIG. 1 is a cross-sectional view illustrating a LCD panel display with the antistatic film of the present invention according to an embodiment; and

FIG. 2 is a cross-sectional view illustrating an OELD panel display with the antistatic film of the present invention according to an embodiment.

### DETAILED DESCRIPTION OF PREFERRED EMBODIMENTS

The present invention provides a conductive composition solution, and an antistatic film and a panel display thereof. One of the objects is providing the transparent coating material having antistatic properties conforming to optical products and without reducing visible range. Another one of the objects is providing antistatic curable coating material, wherein an antistatic film formed thereby can discharge electrostatic without conducting element circuits and power consumption can be reduced. Moreover, it has low fog density, high hardness and anti-scratch properties, and is suitable to grow a conductive coating layer applied in panel displays (e.g., LCD and OELD). Further, the antistatic film as above mentioned includes conductive polymers and silane structure, and therefore it can replace conventional expensive ITO layer and other antistatic material. It can effectively discharge static electricity on a surface of an electronic device by coating the antistatic composition of the present invention on a substrate of the devices and achieve the desired antistatic effect in order to prevent the electronic devices from damage by ESD). Moreover, the material of the present invention meets the coating requirements by adjusting leveling properties, especially coating on a substrate containing silicon, and its hardness can reach greater than 5H preventing damage by wheel movement in manufacturing process thereby increasing the durability of the products.

The above objects together with others characteristics will become clear to those skilled in the art from the following below illustration of the present conductive composition solution and preparation method of the antistatic film thereof. In order to specifically describe the present invention and its efficacy, the examination result of different embodiments and comparative examples are provided.

The present invention provides the conductive composition solution, be as material for forming an antistatic film coating, comprising: an (A) conductive polymer, a (B) alkoxy silane, a (C) solvent and selectively a (D) leveling agent. The (A) conductive polymer comprising: an (a) Π-conjugated conductive polymer and a (b) multivalent anionic polymer, wherein the (b) multivalent anionic polymer is mixed with the (a) Π-conjugated conductive polymer. The (A) conductive polymer has a weight percentage to the conductive composition solution in a range of 0.005-0.1 wt %; the (B) alkoxy silane has a weight percentage to the conductive composition solution in a range of 1-10 wt %; and the (C) solvent comprises a low-boiling-point solvent, having a boiling point in a range of 55-120° C., and a water-soluble-high-boiling-point solvent, having a boiling point in a range of 170-250° C., and water. The conductive composition solution of the present invention as above mentions has a viscosity in a ratio of 3 to 5 cP.

The (A) Conductive Polymer

The (A) conductive polymer in the conductive composition solution of the present invention is an organic polymer and water-soluble, wherein the (a) Π-conjugated conductive polymer is selected from at least one or any combination of the following: polythiophenes, polypyrroles, polyphenylenes, polyanilines and polybenzos; and the (b) multivalent anionic polymer has at least one or any combination of the following: a sulfo group, a phosphoryl group and a carboxyl group. The preferred (A) conductive polymer of the present invention is the poly(3,4-ethylenedioxythiophene): polystyrene sulfonate (PEDOT:PSS), and a preferred weight percentage of the (A) conductive polymer to the conductive composition solution is in a range of 0.01-0.1 wt %.

The (B) Alkoxy Silane

The (B) alkoxy silane in the conductive composition solution of the present invention can be any kinds of silicone precursors, such as tetramethoxysilane (TMOS), tetraethoxysilane (TEOS) or any combination thereof. Moreover, the (B) alkoxy silane has a preferred weight percentage to the conductive composition solution in a range of 1-5.5 wt %.

The (C) Solvent

The (C) solvent in the conductive composition solution of the present invention includes: the low-boiling-point solvent, the high-boiling-point solvent, and water. The low-boiling-point solvent has a boiling point in a range of 55-120° C., such as IPA, ethanol, ketones or any combination thereof, and a weight percentage to the (C) solvent in a range of 55-81 wt %. The high-boiling-point solvent has a boiling point in a range of 170-250° C., such as ethylene glycol (EG), high-carbon alcohols, N-Methylpyrrolidinone (NMP), dimethylsulfoxide (DMSO) or any combination thereof, and a weight percentage to the (C) solvent in a range of 1-15 wt %. The water has a weight percentage to the (C) solvent in a range of 10-30 wt %. Preferably, the low-boiling-point solvent is IPA because it is soluble in both water and the (B) alkoxy silane, which is soluble in organic solvents.

The (D) Leveling Agent

The (D) leveling agent selectively included in the conductive composition solution of the present invention, can be selected from at least one or any combination of the followings: hydroxyl polyester modified siloxanes, acrylic ester copolymers, polyether modified siloxanes, aralkylalkyl modified siloxane, wherein the preferred (D) leveling agent is polyether modified siloxane leveling agent. The (D) leveling agent has a weight percentage to the conductive composition solution in a range of 0.01-1.0 wt %.

Although the conductive polymer has great properties for using as an antistatic film compared with the conventional ITO and/or other antistatic materials, the conductive polymer is hard to synthesize and apply in antistatic material due to its chemical properties resulting in poor mixing properties with polymer/monomer of organic solvents, and especially proportion of ingredients is hardly adjusted or controlled. The (A) conductive polymer in low proportion is non-conductive, but high proportion of the (A) conductive polymer may result in high conductivity and conducting device circuits. Furthermore, because the conductive polymer is water-soluble, there are difficulties to meet the required properties (e.g., environmental resistances, including thermal tolerance and water resistance) of a product in the market. Nevertheless, a cured film that grown through curing the conductive composition solution of the present invention as above mentioned provides good the antistatic effects, high hardness, great weather resistances, etc., that the cured film meet desired qualities/requirements to be applied as an antistatic film in a displaying device.

Besides the regulation of ratios/proportions of the (A) conductive polymer, above mentioned other components also affect coating performances and curing results. The ratio of the (B) alkoxy silane affects hardness and water-resistance of the cured film (as above mentioned, the (B) alkoxy silane has a weight percentage to the conductive composition solution in a range of 1-10 wt %, which preferably is in the range of 1-5.5 wt %). Examination results demonstrate that the film structure does not have enough compactness when a weight percentage of the (B) alkoxy silane is less than 1 wt % and a hardness of the film is too low. However, when a weight percentage of the (B) alkoxy silane, which is nonconductor, is more than 10 wt %, the conductive composition solution has too much nonconductors, and the effect of the nonconductor is stronger than that of the (A) conductive polymer, it results in high resistance on the surfaces and also nonconductivity. Thus, if a ratio of the (B) alkoxy silane, which is inorganic and non-conductive, is too high, it results in a surface electrical resistance of the cured film is too high to discharge electricity. The inventor has further investigated and discovered that because the (A) conductive polymer and the (B) alkoxy silane are conductive and non-conductive respectively, a ratio between them affects the conductivity of the conductive composition solution. Therefore, besides the independent ratio of the (A) conductive polymer or the (B) alkoxy silane in the conductive composition solution as previous description, there is a range of ratios between the two for achieving the required surface resistance of the antistatic film, wherein a weight ratio of the (B) alkoxy silane to the (A) conductive polymer is in a range of 35-100.

Regarding to the (C) solvent, because the (A) conductive polymer is water-soluble and the (B) alkoxy silane is organic-soluble, the (A) conductive polymer and the (B) alkoxy silane are immiscible with each other. Thus, the present invention provides the composition solution with the range of the (C) solvent as described above through many examinations for controlling the curing temperature less than 120° C. and the coating uniformity during the application of panel display. Moreover, if the present composition solution is applied in a panel display, a temperature of the curing process has to be controlled not higher than 120° C. to prevent damage to the panel display; and at the same time, the composition solution has to have a good leveling property in order to produce a required antistatic film. Thus, after long term research and examinations, the present invention provides the composition solution with the range of the (C) solvent as described above.

Regarding to the (D) leveling agent, it is preferably to use a bipolar leveling agent, which is miscible with both the (A) conductive polymer and the (B) alkoxy silane. A ratio of the (D) leveling agent in the conductive composition solution may also affect the hardness of the film formed thereof after the curing process. As the most of the antistatic films are applied in the display panels (e.g., LCD), therefore the antistatic solution is coated between the polarizer and the glass substrate or between the glass substrate and the display module in the process. In examples of the antistatic solution contacting with the glass substrate, the conductive composition solution preferably includes the (D) leveling agent due to a polarity between the silicon of the conductive composition solution and the glass. Moreover, the preferred (D) leveling agent is fluorine free to stabilize the conductive composition solution in the coating process to make the polymer contained in the conductive composition solution arranged in order (i.e. to neatly stack in the same direction), and therefore to form a antistatic film with a dense stacking structure after the curing process. Hence, choices and/or proportions of the (D) leveling agent used significantly affect performances of the conductive composition solution that if inappropriate and/or wrong proportions of the (D) leveling agent used may cause irregular arrangement in the antistatic film on the glass substrate. If a weight percentage of the (D) leveling agent to the conductive composition solution is more than 1 wt %, the examination results demonstrate it a hardness of the cured film decreases; and in contrast, if a ratio thereof is less than 0.01 wt %, it may affect the leveling property of the antistatic film, especially in cases of the antistatic film growing on the glass substrate.

The present invention not only provides the conductive composition solution as previous description but also the fabricating method for growing a cured/antistatic film thereof and a panel display with the above antistatic film.

The fabricating method of the antistatic film of present invention is to coat the conductive composition solution as previous description on a substrate and then perform a curing process to cure the conductive composition solution to form the antistatic film. As above mentioned, the conductive composition solution includes both hydrophilic and hydrophobic components, and thus it is noted that the inter-miscible ingredients have to mix first to form a bipolar mixture before mixing with others ingredients (e.g., adding the ingredients in the order of hydrophilic, bipolar and then hydrophobic or vice versa). For example, (S1) dissolving an (B) alkoxy silane in the low-boiling-point solvent, having the boiling-point in the range of 55° C.-120° C.; (S2) adding the water-soluble high-boiling-point solvent, having a boiling-point in the range of 170° C.-250° C.; (S3) adding water; and (S4) adding a (A) conductive polymer to form the conductive composition solution. After preparing the conductive composition solution. In order to form an antistatic film, after formation of the conductive composition solution, steps of (S5) and (S6) are performed: (S5) coating the conductive composition solution onto a substrate (e.g., glass substrate); and (S6) baking under 80° C.-150° C. for 3-30 minutes to form the antistatic film.

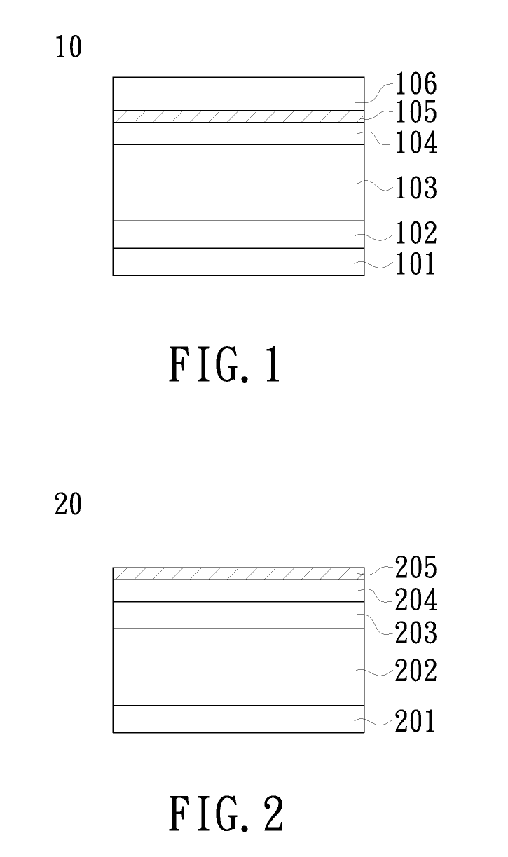

According to the above illustrated conductive composition solution and antistatic film provided by the present invention, the present invention also provides a structure of a panel display including the antistatic film. As shown in FIG. 1, the LCD panel display 10 is drawn according to one embodiment of the present invention. It is noted that FIG. 1 and the LCD panel display in the below description is for illustration only but not intend to limit the present invention. The conductive composition solution and the antistatic film thereof of the present invention are able to be apply to other kinds of displays or operation panels.

In the application of a display, the antistatic film of the present invention directly covers the display and is on a light-emitting side of the display. As shown in FIG. 1, the LCD display 10 sequentially comprises: a backlight module 101, an lower polarizer 102, a display element module 103, a upper polarizer 104, an antistatic film 105 and a glass 106, wherein the display element module 103 comprises: a bottom substrate, a TFT (thin film transistor) element layer, a bottom electrode, a liquid crystal layer, a top electrode, a color filter and a top substrate (the above elements of the display element module 103 are not shown; and the structure of the display element module 103 can be conventional). In those embodiments of touch panel displays, the display element module 103 further includes a touch sensor layer. The above embodiments and figures are for illustration only but not intend to limit the present invention. Moreover, as previous description, the antistatic film directly covers on a polarizer of a display and locates on the lighting side of the display (as shown in FIG. 1, the antistatic film 105 directly contacts with the upper polarizer 104 and on a side of the upper polarizer 104 close to the glass 106); therefore, as in other embodiments of the present invention, the antistatic film 105 is located between the display element module 103 and the upper polarizer 104, or a number of the antistatic film 105 can be plural located on both the two opposite sides of the upper polarizer 104.

In other kinds of the panel display, e.g. the OELD 20 as shown in FIG. 2, sequentially comprises: a under substrate 201, a display element module 202, a top substrate 203, a polarizer 204 and a antistatic film 205, wherein a lighting side is on a side of the display element module 202 close to the polarizer 204 in the present embodiment. The display element module 202 comprises: a cathode, an electron transport layer, an emissive layer, a hole transport layer and an anode (the structure of the display element module 202 can apply conventional structure of an OELD, and thus the above elements are not illustrated in FIG. 2). In another embodiment of the OELD, a touch sensor layer can be selectively included. In addition, the under substrate 201 and the top substrate 203 are not limited to a hard substrate, a flexible substrate, and the under substrate 201 and top substrate 203 individually can be glass substrates or organic material stacking layers, which is not limited herein. Furthermore, the antistatic film as in the previous description is required to directly cover a polarizer close to the lighting side of the display, but an exact position of the antistatic film is not limited herein. In some embodiments of the present invention, the antistatic film 205 is located between the polarizer 204 and the top substrate 203 and directly covers on and attaches to the polarizer 204, or a number of the antistatic film 205 can be plural located on both the two opposite sides of the polarizer 204.

Preferred embodiments of the present invention will be described in detail below for illustration only but not intend to limit the present invention.

According to an embodiment 1 of the present invention, the conductive composition solution comprises (A1) PEDOT:PSS, having a weight percentage of 0.1 wt % to the conductive composition solution; (B1) TEOS, having a weight percentage of 3.5 wt % to the conductive composition solution; (C1) solvents including IPA as the low-boiling-point solvent, NMP as a high-boiling-point solvent and water, wherein a weight ratio of water:the low-boiling-point solvent:the high-boiling-point solvent is 22:66:12; and a (D1) polyether modified siloxane leveling agent having a concentration of 350 ppm. Furthermore, a ratio of (B1) to (A1) is 35. The conductive composition solution is made following the manufacturing principles and the processes as above description.

According to an embodiment 2 of the present invention, the conductive composition solution comprises (A2) PEDOT:PSS, having a weight percentage of 0.1 wt % to the conductive composition solution; (B2) TEOS, having a weight percentage of 4.75 wt % to the conductive composition solution; (C2) solvents including IPA as the low-boiling-point solvent, DMSO as the high-boiling-point solvent, wherein a weight ratio of the water:the low-boiling-point solvent:the high-boiling-point solvent is 22:66:12; and a (D2) polyether modified siloxane leveling agent having a concentration of 350 ppm. Furthermore, a ratio of (B2) to (A2) is 48. The conductive composition solution is made following the manufacturing principles and the processes as above description.

According to an embodiment 3 of the present invention, the conductive composition solution comprises (A3) PEDOT:PSS, having a weight percentage of 0.1 wt % to the conductive composition solution; (B3) TEOS, having a weight percentage of 5.5 wt % to the conductive composition solution; (C3) solvents including IPA as the low-boiling-point solvent, EG as the high-boiling-point solvent, wherein a weight ratio of water:the low-boiling-point solvent:the high-boiling-point solvent is 22:66:12; and a (D3) polyether modified siloxane leveling agent, having a concentration of 350 ppm. Furthermore, a ratio of (B3) to (A3) is 55. The conductive composition solution is made following the manufacturing principles and the processes as above description.

According to an embodiment 4 of the present invention, the conductive composition solution, comprising: (A4) PEDOT:PSS, having a weight percentage of 0.08 wt % to the conductive composition solution; (B4) TEOS, having a weight percentage of 3.5 wt % to the conductive composition solution; (C4) solvents including IPA as the low-boiling-point solvent, NMP as the high-boiling-point solvent, wherein a weight ratio of water:the low-boiling-point solvent:the high-boiling-point solvent is 22:66:12; and a (D4) the polyether modified siloxane leveling agent, having a concentration of 350 ppm. Furthermore, a ratio of (B4) to (A4) is 44. The conductive composition solution is made following the manufacturing principles and the processes as above description.

According to an embodiment 5 of the present invention the conductive composition solution comprises (A5) PEDOT:PSS, having a weight percentage of 0.04 wt % to the conductive composition solution; (B5) TEOS, having a weight percentage of 3.2 wt % to the conductive composition solution; (C5) solvents including ethanol as the low-boiling-point solvent, NMP as the high-boiling-point solvent, wherein a weight ration of water:the low-boiling-point solvent:the high-boiling-point solvent is 22:66:12; and a (D5) polyether modified siloxane leveling agent, having a concentration of 350 ppm. Furthermore, a ratio of (B5) to (A5) is 80. The conductive composition solution is made following the manufacturing principles and the processes as above description.

According to an embodiment 6 of the present invention, the conductive composition solution comprises: (A6) PEDOT:PSS, having a weight percentage of 0.03 wt % to the conductive composition solution; (B6) TMOS, having a weight percentage of 1.05 wt % to the conductive composition solution; (C6) solvents including IPA as the low-boiling-point solvent, NMP as the high-boiling-point solvent, wherein the weight ration of water:the low-boiling-point solvent:the high-boiling-point solvent is 22:66:12; and a (D6) polyether modified siloxane leveling agent, having the concentration of 350 ppm. Furthermore, a ratio of (B6) to (A6) is 35. The conductive composition solution is made following the manufacturing principles and the processes as above description.

According to an embodiment 7 of the present invention, the conductive composition solution comprises (A7) PEDOT:PSS, having a weight percentage of 0.03 wt % to the conductive composition solution; (B7) TEOS, having a weight percentage of 1.05 wt % to the conductive composition solution; (C7) solvents including IPA as the low-boiling-point solvent, EG as the high-boiling-point solvent, wherein a weight ration of water:the low-boiling-point solvent:the high-boiling-point solvent is 17:81:2; and a (D7) polyether modified siloxane leveling agent, having the concentration of 350 ppm. Furthermore, a ratio of (B7) to (A7) is 35. The conductive composition solution is made following the manufacturing principles and the processes as above description.

According to an embodiment 8 of the present invention, the conductive composition solution comprises (A8) PEDOT:PSS, having a weight percentage of 0.01 wt % to the conductive composition solution; (B8) TEOS, having a weight percentage of 1 wt % to the conductive composition solution; (C8) solvents including IPA as the low-boiling-point solvent, EG as the high-boiling-point solvent, wherein a weight ratio of water:the low-boiling-point solvent:the high-boiling-point solvent is 17:81:2; and a (D8) polyether modified siloxane leveling agent, having the concentration of 350 ppm. Furthermore, a ratio of (B8) to (A8) is 100. The conductive composition solution is made following the manufacturing principles and the processes as above description.

The effects of the present invention will become more readily apparent to those ordinarily skilled in the art after reviewing the following detailed ingredients, examinations and result descriptions of the examples 1-3 as provided below, whereby comparing the examples 1-3 to the embodiments 1-8.

An example 1, wherein the conductive composition solution comprises (A11) PEDOT:PSS, having a weight percentage of 0.005 wt % to the conductive composition solution; (B11) TEOS, having a weight percentage of 0.5 wt % to the conductive composition solution; (C11) solvents including ethanol as the low-boiling-point solvent, NMP as the high-boiling-point solvent and water, wherein a weight ratio of water:the low-boiling-point solvent:the high-boiling-point solvent is 5:93:2; and without a leveling agent. Furthermore, the ratio of (B11) to (A11) is 100. The conductive composition solution is made following the manufacturing principles and the processes as above description.

An example 2, wherein the conductive composition solution comprises (A12) PEDOT:PSS, having a weight percentage of 0.01 wt % to the conductive composition solution; (B12) TEOS, having a weight percentage of 1 wt % to the conductive composition solution; (C12) solvents including ethanol as the low-boiling-point solvent, EG as the high-boiling-point solvent and water, wherein a weight ration of water:the low-boiling-point solvent:the high-boiling-point solvent is 1:84:15; and a (D12) polyether modified siloxane leveling agent, having a concentration of 350 ppm. Furthermore, the ratio of (B12) to (A12) is 100. The conductive composition solution is made following the manufacturing principles and the processes as above description.

An example 3, wherein the conductive composition solution comprises (A13) PEDOT:PSS, having a weight percentage of 0.03 wt % to the conductive composition solution; (B13) TEOS, having a weight percentage of 3.6 wt % to the conductive composition solution; (C13) solvents including ethanol as the low-boiling-point solvent, NMP as the high-boiling-point solvent and water, wherein a weight ratio of water:the low-boiling-point solvent:the high-boiling-point solvent is 22:66:12; and (D13) polyether modified siloxane leveling agent, having the concentration of 350 ppm. Furthermore, a ratio of (B13) to (A13) is 120. The conductive composition solution is made following the manufacturing principles and the processes as above description.

As the above description, an electronic resistance value of the antistatic film to be functioned as required has to be in the range of 10⁶-10¹²Ω/□, and which preferably is in the range of 10⁸-10¹⁰Ω/□. During panel display manufacturing process, the transport/movement of a panel display is trough wheels/roller on a production line and the elements/devices of the aforesaid panel display may be fabricated by different companies and then assembled thereafter. Generally, in order to prevent scratches and damage of devices on a production line, a hardness value of an outside antistatic film is required to be above 5H. Moreover, a stability of a product is important, and it is required to have good weather resistance. Hence, examinations on the surface electronic resistance (Ω/□), the hardness (H) and the weather resistance to the examples 1-3 and the embodiments 1-8 are performed and the detailed description is showing as below.

According to the previous fabricating method of an antistatic film, the conductive composition solutions from the examples 1-3 and the embodiments 1-8 are coated on glass substrates and cured to form antistatic films respectively. After, examinations are performed. The values of the surface resistance (Ω/□) and the hardness (H) are both directly detected, but the weather resistance is through indirect method. The antistatic films from the comparative examples and the embodiments are soaked in water at a temperature above 95° C. for 16 hours and their surface electronic resistances are then tested. Furthermore, a stable electronic resistance (weather resistance) means a change between the surface electronic resistances before and after soaking must less than a power of number of 2 (i.e., the variation smaller than or equal to a power of 1) and the better one is without changing. The examination results are shown in the Table 1 as below and, furthermore, the results from the Table 1 are classified by the symbols as shown in the Table 2 for clear demonstration. According to the Table 2, it is obvious that all the embodiments (embodiments 1-8) are qualified and the antistatic films with preferred ingredient ratios in the preferred ranges as described above also have better results. Although it does not show in the Table 2, regarding to the leveling property in the examples 1-3 and the embodiments 1-8, the conductive composition solution without the leveling agent in the example 1 is significantly poor then others examples after coating on a substrate.

The results from the embodiment 8 and the example 2 demonstrate the conductive polymer is difficult to uniformly mix with organic polymers/monomers. The results from the embodiment 6, the embodiment 7 and the example 3 demonstrate the ratio of the (B) alkoxy silane to the (A) conductive polymer is too high, and an antistatic film becomes nonconductive because the value of the surface electronic resistance is too high. Although PEDOT:PSS, which is a well-known commercial polymer, can be selected to be the conductive polymer of the present invention, the conventional PEDOT:PSS is not sufficient for applying as an antistatic film. For example, a Japanese patent (publication number 2004-532292) demonstrates a method used to overcome the defects of aqueous dispersions of PEDOT:PSS, wherein the method uses low alcohols that easily mix with water, to substitute parts of organic solvents in the aqueous dispersion, and thereby it is used as an aqueous organic dispersion. Because the adhesive polymers/monomers are less soluble in alcohols, sometimes a coated layer happens to transparency decreasing, for the reason using organic solvents and adhesive polymers/monomers at the same time, and which clearly illustrates it is difficult to apply. However, the present invention provides the conductive composition solution that is able to fabricate the required antistatic film.

TABLE 1

| | | | 95° C./16 hrs |
|---|---|---|---|
| | | Surface | Surface |
| | | resistance | resistance |
| | Hardness | (Ω/□) | (Ω/□) |
| Example 1 | 8H | 3*10⁹ | 10⁹ -> 10¹¹ |
| Example 2 | 3H | 7*10¹⁰ | 10¹⁰ -> 10¹¹ |
| Example 3 | 8H | 5*10¹³ | 10¹³ -> 10¹³ |
| Embodiment 1 | 7H | 3*10⁷ | 10⁷ -> 10⁸ |
| Embodiment 2 | 6H | 2*10⁸ | 10⁸ -> 10⁹ |
| Embodiment 3 | 5H | 4*10⁹ | 10⁹ -> 10¹⁰ |
| Embodiment 4 | 7H | 2*10¹² | 10¹² -> 10¹² |
| Embodiment 5 | 6H | 3*10⁸ | 10⁸ -> 10⁹ |
| Embodiment 6 | 9H | 7*10⁸ | 10⁸ -> 10⁹ |
| Embodiment 7 | 9H | 5*10⁹ | 10⁹ -> 10⁹ |
| Embodiment 8 | 9H | 3*10¹⁰ | 10¹⁰ -> 10¹⁰ |

TABLE 2

| | | Surface | |
|---|---|---|---|
| | | resistance | Weather |
| | Hardness | (Ω/□) | resistance |
| Example 1 | ◯ | ⊚ | X |
| Example 2 | X | ⊚ | Δ |
| Example 3 | ◯ | X | ◯ |
| Embodiment 1 | ◯ | ◯ | Δ |
| Embodiment 2 | ◯ | ⊚ | Δ |
| Embodiment 3 | ◯ | ⊚ | Δ |
| Embodiment 4 | ◯ | ◯ | ◯ |
| Embodiment 5 | ◯ | ⊚ | Δ |
| Embodiment 6 | ⊚ | ⊚ | Δ |
| Embodiment 7 | ⊚ | ⊚ | ◯ |
| Embodiment 8 | ⊚ | ⊚ | ⊚ |

Note:
hardness: ⊚ (9H), O (8H-5H), X (<4H);
surface resistance: ◯ (10⁶⁻⁸ [symbol] 10¹⁰⁻¹²), ⊚ (10⁸⁻¹⁰) , X(>10⁶⁻¹² or <10⁶⁻¹²); and
weather resistance: ◯ (no change of the power of the value), Δ (the change of the power of value smaller than or equal to 1), X (the change of the power of value greater than or equal to 2).

Although the embodiments of the present invention have described as previous, it is to be understood that modifications will be apparent to those skilled in the art without departing from the spirit of the invention. The scope of the invention, therefore, is to be determined solely by the following claims.

What is claimed is:

1. A conductive composition solution, comprising:
an (A) conductive polymer, comprising:
a Π-conjugated conductive polymer; and
a multivalent anionic polymer, wherein the multivalent anionic polymer is mixed with the Π-conjugated conductive polymer;
a (B) alkoxy silane, having a weight percentage to the conductive composition solution in a range of 1-5.5 wt %; and
a (C) solvent, comprising:
a low-boiling-point solvent, having a boiling point in a range of 55-120° C.;
a high-boiling-point solvent having a boiling point in a range of 170-250° C. and soluble in water; and
water.

2. The conductive composition solution of claim 1, wherein the (A) conductive polymer is a poly(3,4-ethylenedioxythiophene)-poly (styrenesulfonate).

3. The conductive composition solution of claim 1, wherein a weight percentage of the (A) conductive polymer to the conductive composition solution is in a range of 0.01-0.1 wt %.

4. The conductive composition solution of claim 1, wherein a weight ratio of the (B) alkoxy silane to the (A) conductive polymer is in a range of 35-100.

5. The conductive composition solution of claim 1, wherein a weight percentage of the low-boiling-point solvent to the (C) solvent is in the range of 55-81 wt %; a weight percentage of the high-boiling-point solvent to the (C) solvent is in the range of 1-15 wt %; and a weight percentage of the water to the (C) solvent is in the range of 10-30 wt %.

6. The conductive composition solution of claim 1, wherein the (B) alkoxy silane is selected from at least one or any combination of the following: a tetramethoxysilane and a tetraethoxysilane.

7. The conductive composition solution of claim 1, wherein the low-boiling-point solvent is selected from at least one or any combination of the following: isopropanol (IPA), ethanol and ketones.

8. The conductive composition solution of claim 1, wherein the high-boiling-point solvent is selected from at least one or any combination of the following: ethylene glycols, high-carbon alcohols, N-Methylpyrrolidinones and dimethylsulfoxides.

9. The conductive composition solution of claim 1, further comprising:
a (D) leveling agent having a weight percentage to the conductive composition solution is in a range of 0.01-1.0 wt %.

10. An antistatic film, formed by coating and curing the conductive composition solution of claim 1.

11. The antistatic film of claim 10, wherein the antistatic film is formed by curing the conductive composition solution under 80-150° C. for 3-30 minutes.

12. The antistatic film of claim 10, wherein a hardness of the antistatic film is 5H or above.

13. The antistatic film of claim 10, wherein a surface resistance of the antistatic film is in the range of 10⁶Ω/□˜10¹²Ω/□.

14. A panel display, comprising the antistatic film of claim 10.

15. The panel display of claim 14, further comprising:
a polarizer, wherein the antistatic film of claim 10 covers directly on the polarizer.

16. The panel display of claim 15, wherein the panel display is a liquid crystal display, and the panel display further comprises a glass and a display element module, the polarizer is interposed between the glass and the display element module, the antistatic film is deposed on the polarizer at a first side close to the glass, at a second side close to the display element module, or at both the first and the second sides.

17. The panel display of claim 15, wherein the panel display is an organic electro-luminescene display, and the panel display further comprises a display element module, wherein the antistatic film is deposed on the polarizer at a first side close to the display element module, at a second side opposite to the first side away from the display element module, or at both the first and the second sides.
